(19) United States
(12) Patent Application Publication
(10) Pub. No.: US 2008/0044773 A1
(43) Pub. Date: Feb. 21, 2008

(54) METHOD OF MANUFACTURING A PATTERNED COLOR CONVERSION LAYER, AND METHODS OF MANUFACTURING A COLOR CONVERSION FILTER AND AN ORGANIC EL DISPLAY THAT USE A COLOR CONVERSION LAYER OBTAINED BY THE METHOD

(75) Inventor: Yukinori KAWAMURA, Matsumoto City (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO., LTD., Kawasaki-ku (JP)

(21) Appl. No.: 11/830,939

(22) Filed: Jul. 31, 2007

(30) Foreign Application Priority Data
Aug. 3, 2006 (JP) 2006-212232

(51) Int. Cl. G03C 5/00

(52) U.S. Cl. 430/314

(57) ABSTRACT

A method of manufacturing a color conversion layer with a predetermined pattern is disclosed which does not cause any damage on the color conversion layer formed by a dry process such as an evaporation method to achieve a large scale and high definition. The method includes steps of sequentially forming, on a substrate, an etch stop layer, a color conversion layer by means of an evaporation method, a protective layer and a transparent mask layer; patterning a resist layer formed on the transparent mask layer to have a predetermined pattern; transferring the pattern from the resist layer to the transparent mask layer using the patterned resist layer as a mask; removing the patterned resist layer; and dry etching, using the patterned transparent mask layer as a mask, to transfer the pattern to the protective layer and the color conversion layer.

### CROSS REFERENCE TO RELATED APPLICATIONS

This application is based on, and claims priority to, Japanese Patent Application No. 2006-212232, filed on Aug. 3, 2006, the contents of which are incorporated herein by reference in their entirety.

### BACKGROUND OF THE INVENTION

A. Field of the Invention

The present invention relates to a method of patterning a color conversion layer formed by an evaporation method. The invention also relates to a color conversion filter and an organic EL display, the filter and the display using a color conversion layer obtained by the patterning method. Color conversion filters and organic EL displays obtained by the method of the invention can be used in multi-color light emitting organic EL devices, which are installed in personal computers, word processors, TV sets, facsimiles, audio sets, video recorders, car navigations, electronic calculators, telephones, mobile terminals, industrial instruments, and other equipment.

B. Description of the Related Art

Recently there has been active research relating to practical applications of organic EL devices. Organic EL devices, which are capable of obtaining high current density at a low voltage, are expected to achieve high luminance and efficiency. It is anticipated for organic multi-color EL displays to achieve high definition multi-color or full color display. A method to obtain multi-color or full color with an organic EL display has been proposed that uses a color conversion method with a patterned color conversion film and an organic EL device, the latter including a plurality of independent light emitting elements and emitting monochromatic light. See Japanese Unexamined Patent Application Publication No. 2002-75643 (corresponding to US Patent Application Publication No. US 2001/0043043); Japanese Unexamined Patent Application Publication No. 2003-217859 (corresponding to U.S. Pat. No. 6,781,304) and Japanese Unexamined Patent Application Publication No. 2000-230172. The color conversion film contains one or more color conversion materials that absorb light in a short wave length region and convert it into light in a longer wave length region. Methods for forming a color conversion film have been studied in which a color conversion material is deposited by a dry process such as evaporation or sputtering.

In a method for patterning a color conversion layer that is formed by depositing a color conversion material employing a dry process such as evaporation or sputtering, a method in which the color conversion material is deposited with a predetermined pattern using a metal mask is generally used.

In another method for achieving a multi-color or full color organic EL display, a so-called “patterned RGB method” has been studied in which plural types of organic EL light emitting elements emitting different colors (for example, three primary colors: red (R), green (G) and blue (B)) are formed. In the method that has been studied for forming the plural types of organic EL light emitting elements with a predetermined pattern, a resist mask is used for dry-etching a lamination structure that includes an organic EL layer and electrodes formed by a dry process such as evaporation. See Japanese Unexamined Patent Application Publication No. H9-293589 (corresponding to U.S. Pat. No. 5,953,585); Japanese Unexamined Patent Application Publication No. 2000-113981 and Japanese Unexamined Patent Application Publication No. 2000-113982 (corresponding to U.S. Pat. No. 6,120,338).

It has proved difficult, however, to expand the area of formed color conversion layer to form a color conversion layer by means of evaporation method employing a metal mask. Moreover, this method currently is reaching a limit in forming a pattern with high definition.

In the dry etching technique using a resist mask in the above-described “patterned RGB method,” which forms plural types of organic EL light emitting elements with a predetermined pattern, the resist mask must be removed in order to eliminate the unfavorable influence of the remaining resist mask on optical performance of the obtained display. The process for removing the resist mask is carried out in the condition with the side edge of the evaporated film being exposed to the surroundings after the dry etching process. As a result, the evaporated film, which is free of any binding agent, suffers damage in the process of removing the resist mask either employing a dry process such as oxygen plasma ashing or employing a wet process with a solvent.

The present invention is directed to overcoming or at least reducing the effects of one or more of the problems set forth above.

### SUMMARY OF THE INVENTION

It is therefore an object of the present invention to provide a method of manufacturing a color conversion layer with a predetermined pattern without any damage to the color conversion layer formed by a dry process such as evaporation to achieve both large scale and high definition. Another object of the invention is to provide a method of manufacturing a color conversion filter utilizing the method of manufacturing a patterned color conversion layer. Still another object of the invention is to provide a method of manufacturing an organic EL display utilizing the method of manufacturing a patterned color conversion layer.

To achieve the above objects, a first embodiment according to the invention comprises steps of:

(a) forming an etch stop layer on a substrate;

(b) forming a color conversion layer on the etch stop layer by means of an evaporation method;

(c) forming a protective layer covering the color conversion layer;

(d) forming a transparent mask layer on the protective layer;

(e) forming a resist layer on the transparent mask layer;

(f) patterning the resist layer in a predetermined pattern;

(g) transferring the pattern in the resist layer to the transparent mask layer using the patterned resist layer as a mask;

(h) removing the patterned resist layer; and

(i) dry etching, using the patterned transparent mask layer as a mask, to transfer the pattern from the transparent mask layer to the protective layer and the color conversion layer.

The etch stop layer can be formed of an oxide containing an element selected from a group consisting of indium, zinc, aluminum, zirconium and titanium. The transparent mask layer can be formed of an oxide containing indium or zinc. The color conversion layer can have a thickness of at most 1 μm. The protective layer can be formed of a silicon oxide, a silicon nitride or a silicon oxide nitride, each being transparent. The step (i) can be carried out by means of a reactive ion etching method.

A second embodiment according to the invention comprises steps of:

(a-1) forming one or more types of color filter layers on a substrate;

(a-2) forming an etch stop layer covering the color filter layers;

(b) forming a color conversion layer on the etch stop layer by means of an evaporation method;

(c) forming a protective layer covering the color conversion layer;

(d) forming a transparent mask layer on the protective layer;

(e) forming a resist layer on the transparent mask layer;

(f) patterning the resist layer in a predetermined pattern;

(g) transferring the pattern in the resist layer to the transparent mask layer using the patterned resist layer as a mask;

(h) removing the patterned resist layer; and

(i) dry etching, using the patterned transparent mask layer as a mask, to transfer the pattern from the transparent mask layer to the protective layer and the color conversion layer.

A third embodiment according to the invention comprises steps of:

(a-1) forming a plurality of switching elements, a reflective electrode of a plurality of electrode elements each connecting to each of the plurality of switching elements in a one to one corresponding manner, and an organic EL layer on the reflective electrode;

(a-2) forming a monolithic transparent electrode on the organic EL layer;

(a-3) forming an etch stop layer over the transparent electrodes;

(b) forming a color conversion layer on the etch stop layer by means of an evaporation method;

(c) forming a protective layer covering the color conversion layer;

(d) forming a transparent mask layer on the protective layer;

(e) forming a resist layer on the transparent mask layer;

(f) patterning the resist layer in a predetermined pattern;

(g) transferring the pattern in the resist layer to the transparent mask layer using the patterned resist layer as a mask;

(h) removing the patterned resist layer; and

(i) dry etching, using the patterned transparent mask layer as a mask, to transfer the pattern from the transparent mask layer to the protective layer and the color conversion layer.

Alternatively, the steps (a-2) and (a-3) can be replaced by a step (a-4) of forming, on the organic EL layer, an etch stop layer that simultaneously performs the function of a monolithic transparent electrode and is formed of an oxide containing indium or zinc.

According to the invention, a pattern can be formed on a color conversion layer deposited by a dry process such as an evaporation method to provide a patterned color conversion layer. Through function separation between a resist layer for pattern-forming and a mask for dry etching, compatibility has been achieved between a formed layer having a large area and high definition of the formed pattern. The mask made of a transparent material precludes the necessity for removing the mask after dry etching and avoids damage to the patterned color conversion layer obtained. This method of manufacturing a patterned color conversion layer exhibits the same effect in applications to manufacturing a color conversion filter and manufacturing an organic EL display.

### BRIEF DESCRIPTION OF THE DRAWINGS

The foregoing advantages and features of the invention will become apparent upon reference to the following detailed description and the accompanying drawings, of which:

FIGS. 1(a) through 1(e) show a manufacturing process of a patterned color conversion layer, the process being the first embodiment according to the invention and showing steps in the order in the manufacturing process;

FIG. 2 shows a color conversion filter obtained by the second embodiment according to the invention; and

FIG. 3 shows an organic EL display obtained by the third embodiment according to the invention.

### DETAILED DESCRIPTION OF SPECIFIC EMBODIMENTS

A method of manufacturing a patterned color conversion layer of a first embodiment according to the invention comprises steps of:

(a) forming an etch stop layer on a substrate;

(b) forming a color conversion layer on the etch stop layer by means of an evaporation method;

(c) forming a protective layer covering the color conversion layer;

(d) forming a transparent mask layer on the protective layer;

(e) forming a resist layer on the transparent mask layer;

(f) patterning the resist layer in a predetermined pattern;

(g) transferring the pattern in the resist layer to the transparent mask layer using the patterned resist layer as a mask;

(h) removing the patterned resist layer; and

(i) dry etching, using the patterned transparent mask layer as a mask, to transfer the pattern from the transparent mask layer to the protective layer and the color conversion layer.

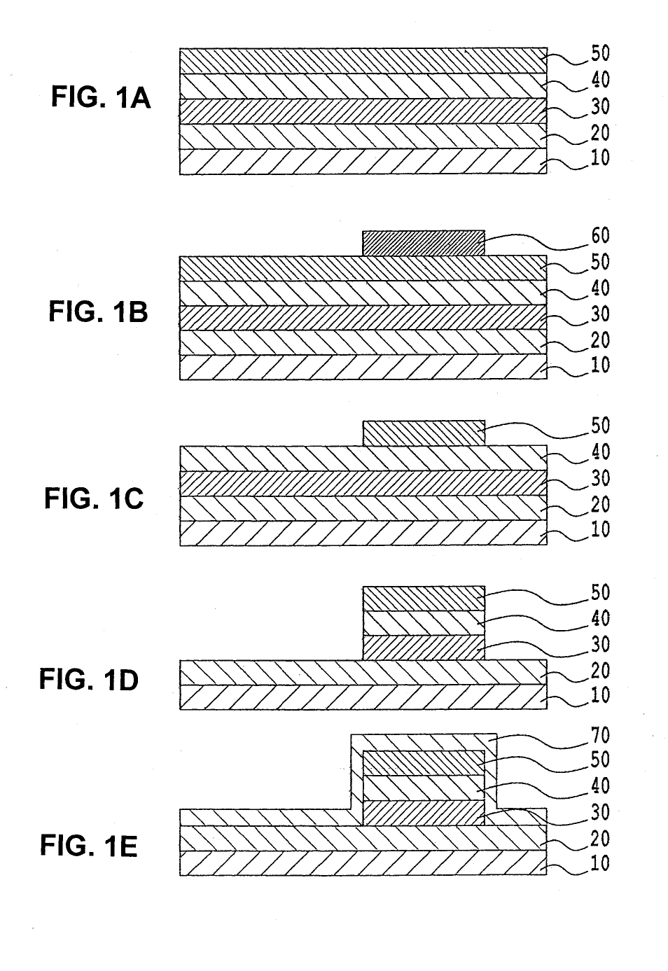

This embodiment will be described hereinafter with reference to FIG. 1. FIG. 1(a) shows a state after step (d), in which layers of etch stop layer 20, color conversion layer 30, protective layer 40 and transparent mask layer 50 are laminated on substrate 10 and are unpatterned. Substrate 10 in this embodiment preferably is made of a transparent self-supporting material, although this depends on the desired practice. Preferred materials for forming substrate 10 include glass and polymer materials, the latter can be selected from: cellulose ester such as diacetyl cellulose, triacetyl cellulose (TAC), propionyl cellulose, butyryl cellulose, acetyl propionyl cellulose and nitro cellulose; polyamide; polycarbonate; polyester such as polyethylene terephthalate, polyethylene naphthalate, polybutylene terephthalate, poly-1,4-cyclohexane dimethylene terephthalate, polyethylene-1,2-diphenoxyethane-4,4′-dicarboxylate; polystyrene; polyolefin such as polyethylene, polypropylene, and polymethyl pentene; acrylic resin such as polymethyl methacrylate; polysulfone; polyether sulfone; polyether ketone; polyether imide; polyoxyethylene; and norbornene resin.

Substrate 10, when formed of a polymer, can be rigid or flexible. When it is said that substrate 10 is “transparent,” it means that the substrate exhibits transmissivity of not lower than 80%, and preferably not lower than 86% to visible light.

Etch stop layer 20 is formed in step (a). In the dry etching process of color conversion layer 30 and protective layer 40, etch stop layer 20 stops the etching process or exhibits an etching speed slower than those of color conversion layer 30 and protective layer 40 (that is, it exhibits a higher selectivity factor). Because the light entering color conversion layer 30 or leaving color conversion layer 30 passes through etch stop layer 20, etch stop layer 20 desirably is transparent. When the dry etching of color conversion layer 30 and protective layer 40 is carried out by means of a reactive ion etching (RIE) technique using an etching gas containing fluorine, etch stop layer 20 can be formed of an oxide containing an element(s) selected from a group consisting of indium, zinc, aluminum, zirconium and titanium, though the material depends on the conditions of the dry etching process. Preferred oxides include transparent conductive oxides of indium oxide, zinc oxide, indium-zinc oxide (IZO), indium-tin oxide (ITO), and oxides of Al₂O₃, ZrO₂ and TiO₂. Etch stop layer 20 can be formed by depositing an oxide film containing indium or zinc employing any appropriate technique known in the art such as sputtering or CVD. To stop the dry etching process and protect the film formed under the etch stop layer, etch stop layer 20 in the invention has a thickness of in the range of 10 to 100 nm, preferably in the range of 30 to 50 nm.

In step (b), color conversion layer 30 is formed on etch stop layer 20. Color conversion layer 30 in this embodiment is formed of one or more types of color conversion dyes. Color conversion layer 30 preferably has a thickness of at most 1 μm, more preferably in the range of 200 nm to 1 μm. Color conversion layer 30 is formed by a dry process, preferably an evaporation method (including resistance heating and electron beam heating). When color conversion layer 30 is formed of a plurality of color conversion dyes, a procedure can be used in which a preliminary mixture is prepared mixing the color conversion dyes in a predetermined proportion and a co-evaporation is conducted using the preliminary mixture. An alternative procedure can be used as well in which the plurality of dyes are arranged at different places and each dye is individually heated to produce co-evaporation. If the color conversion dyes have large differences in material properties such as evaporation speed and vapor pressure, in particular, the latter procedure is effective. A color conversion dye that can be used for forming color conversion layer 30 can be selected from coumarin dyes such as 3-(2-benzothiazolyl)-7-diethylamino coumarin (coumarin 6), 3-(2-benzooimidazolyl)-7-diethylamino coumarin (coumarin 7), and coumarin 135; anphthalimide dyes such as solvent yellow 43 and solvent yellow 44; cyanine dyes such as 4-dicyanomethylene-2-methyl-6-(p-dimethylaminostyryl)-4H-pyrane (DCM-1, (I)), DCM-2 (II), and DCJTB (III); xanthene dyes such as rhodamine B and rhodamine 6G; pyridine dyes such as pyridine 1; 4,4-difluoro-1,3,5,7-tetraphenyl-4-bora-3a,4a,-diaza-s-indacene (IV), lumogen F red, and Nile red (V).

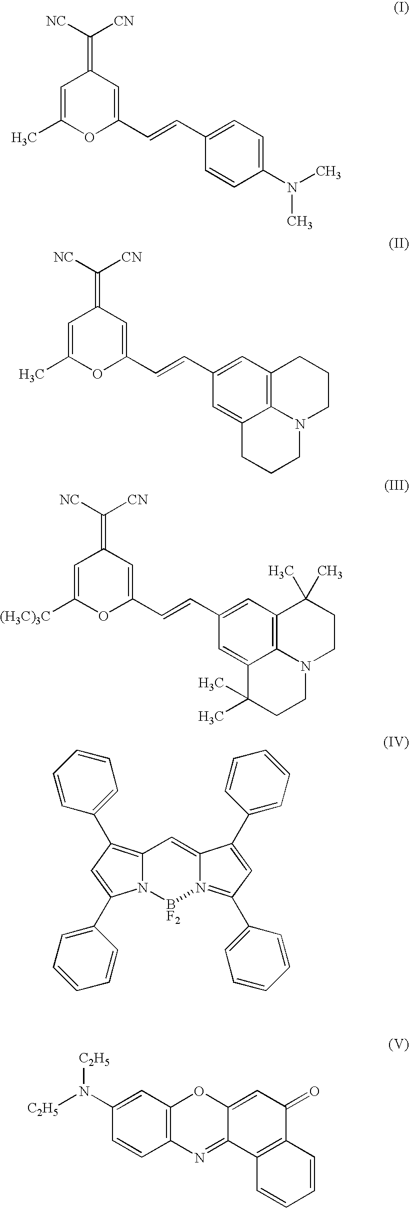

In step (c), protective layer 40 is formed covering color conversion layer 30. Protective layer 40 protects color conversion layer 30 against a solvent to be used in forming resist layer 60 described later, and against a solvent and a developing agent used in patterning resist layer 60. It is desired for protective layer 40 to be removable under conditions for patterning color conversion layer 30 and to be formed under conditions that do not cause any damage on color conversion layer 30. It is further desired for protective layer 40 to be transparent because protective layer 40, like etch stop layer 20, transmits the light entering color conversion layer 30 or the light leaving color conversion layer 30. Preferred materials for forming protective layer 40 include inorganic materials such as silicon oxide, silicon nitride, and silicon oxide nitride. Formation of protective layer 40 can be carried out by depositing these inorganic materials by a dry process such as a CVD method or an evaporation method.

In step (d), transparent mask layer 50 is formed on protective layer 40. Transparent mask layer 50 is patterned by a mask of patterned resist layer 60 and then used as a mask in a dry etching process for actually patterning color conversion layer 30. Accordingly, transparent mask layer 50 is formed of a material that does not permit etching to progress under the conditions of the employed dry etching, or is etched much slower than color conversion layer 30 and protective layer 40. Transparent mask layer 50 also must transmit the light entering color conversion layer 30 or the light leaving color conversion layer 30, and thus is desired to be transparent. When the dry etching process is carried out by reactive ion etching (RIE) using an etching gas containing fluorine, transparent mask layer 50 can be formed of an oxide containing indium or zinc, although this depends on the conditions for dry etching color conversion layer 30 and protective layer 40. Preferred oxides include transparent conductive oxides such as indium oxide, zinc oxide, indium-zinc oxide (IZO), indium-tin oxide (ITO). Transparent mask layer 50 can be formed by depositing a film of oxide containing indium or zinc employing any appropriate technique known in the art such as a sputtering method or a CVD method. To function as an etching mask in step (i), transparent mask layer 50 in the invention has a thickness in the range of 10 to 100 nm, preferably in the range of 30 to 50 nm.

In step (e), resist layer 60 is formed on transparent mask layer 50 to pattern transparent mask layer 50. Resist layer 60 can be a resist material of a negative type or a positive type known in the art, and can be formed by any appropriate technique, such as by spin coating, screen printing, or the like. Subsequently in step (f), resist layer 60 is patterned to obtain patterned resist layer 60 as shown in FIG. 1(b). Patterning of resist layer 60 is carried out by appropriate exposure and development processes to obtain a predetermined pattern depending on the employed resist material.

In step (g), transparent mask layer 50 is patterned using a mask of patterned resist layer 60. It is preferable for this step to be carried out by a wet etching process, although this depends on the material involved. When transparent mask layer 50 is formed of an oxide containing indium or zinc, for example, an acidic solution (for example, an aqueous solution of oxalic acid) can be used for the etching process. Subsequently, in step (h), resist layer 60 that has been used for a mask is removed to obtain a lamination structure having a top layer of patterned transparent mask layer 50 as shown in FIG. 1(c). Removal of resist layer 60 can be carried out by an appropriate method known in the art, such as by cleaning with a solvent or a peeling liquid, depending on the material concerned. Thus, resist layer 60 is only used in the process of patterning transparent mask layer 50, and has been removed before color conversion layer 30 (and protective layer 40) is patterned. Consequently, a material for resist layer 60 does not need resistance to dry etching. The material of resist layer 60 can be selected with a primary object of providing a desired pattern in a large area and with high definition.

In step (i), protective layer 40 and color conversion layer 30 are patterned by a dry etching technique using a mask of patterned transparent mask layer 50. The dry etching proceeds to remove protective layer 40 and color conversion layer 30 in the region without patterned transparent mask layer 50 until etch stop layer 20 is exposed, and stops at that moment. The etching process results in a lamination structure of color conversion layer 30/protective layer 40/transparent mask layer 50 having a configuration following the pattern of transparent mask layer 50 as shown in FIG. 1(d). Both protective layer 40 and transparent mask layer 50, being transparent in the invention, need not be removed after the completion of the patterning process. Therefore, the damage that would be caused by the process of removing these layers is avoided. Transparent mask layer 50 in the invention is patterned using resist layer 60 and need not have the function of patterning by transparent mask layer 50 itself. Therefore, the material of transparent mask layer 50 can be selected based on the important factors of transparency and resistance to dry etching.

It is preferable in this dry etching step to employ a reactive ion etching method using an etching gas containing fluorine, though depending on the materials of the layers. The etching gases include CF₄, CHF₃, CClF₃, CCl₃F, C₂F₆, C₃F₈, C₃F₆, C₄F₁₀, NF₃, SF₆, and HF.

After patterning color conversion layer 30 as described above, overcoat layer 70 can be optionally provided covering the lamination structure of color conversion layer 30/protective layer 40/transparent mask layer 50 to protect the side face of color conversion layer 30, which otherwise would be expose to the atmosphere (FIG. 1(e)). Overcoat layer 70 can be formed using the same material and technique as for protective layer 40.

Optionally, after step (i) in this embodiment, steps (b) through (i) can be repeated to form a patterned color conversion layer of a different type on the same substrate. Here, in repeating step (c), newly formed protective layer 40 preferably protects the previously patterned color conversion layer 30 (FIG. 1(d), of the side face, in particular) as well as the newly formed different type of color conversion layer 30. Further as necessary, by repeating steps (b) through (i) any appropriate times, desired types of color conversion layers having each predetermined pattern can be formed on the same substrate.

The second embodiment of a method of manufacturing a color conversion filter according to the invention comprises steps of:

(a-1) forming one or more types of color filter layers on a substrate;

(a-2) forming an etch stop layer covering the color filter layers;

(b) forming a color conversion layer on the etch stop layer by means of an evaporation method;

(c) forming a protective layer covering the color conversion layer;

(d) forming a transparent mask layer on the protective layer;

(e) forming a resist layer on the transparent mask layer;

(f) patterning the resist layer in a predetermined pattern;

(g) transferring the pattern in the resist layer to the transparent mask layer using the patterned resist layer as a mask;

(h) removing the patterned resist layer; and

(i) dry etching, using the patterned transparent mask layer as a mask, to transfer the pattern from the transparent mask layer to the protective layer and the color conversion layer.

In this embodiment, substrate 10, which transmits light coming through color conversion layer 30 and color filter layer 100, must be formed of a transparent self-supporting material. Preferred materials for forming substrate 10 in this embodiment are the same transparent materials for substrate 10 in the first embodiment.

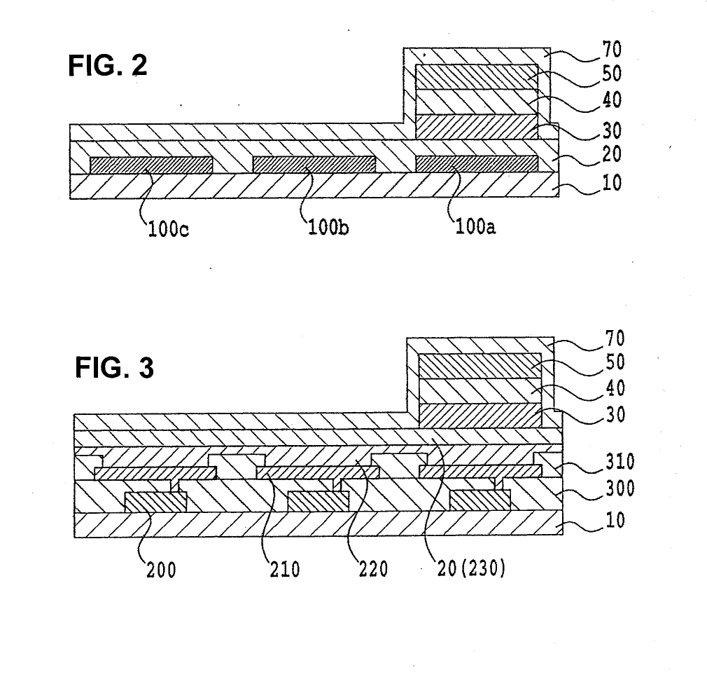

In step (a-1), one or more types of color filter layers 100 are formed on substrate 10. FIG. 2 shows an example having three types of color filter layers 100a, 100b, and 100c. Color filter layer 100 can be formed using any appropriate material commercially available as a material for flat panel displays and by means of known methods of applying and patterning suited for the material involved. Optionally, a planarizing layer (not shown in the figure) can be formed on the color filter layer to obtain a flat surface on the color filter layer. The planarizing layer is composed of a polymer material which exhibits transparency to visible light, provides electric insulation property, and functions as a barrier against moisture, oxygen and low molecular-weight components.

In step (a-2), etch stop layer 20 is formed covering the one or more types of color filter layers 100. Step (a-2) in this embodiment can be carried out using the same material and method as in step (a) of the first embodiment. The thickness of etch stop layer 20 in this embodiment can be the same value as in the first embodiment.

Following these steps, steps (b) through (i) are carried out in the same manner as in the first embodiment to form patterned color conversion layer 30. Patterned color conversion layer 30 is formed at a position corresponding to one of the one or more types of color filter layers 100. In the example of FIG. 2, color conversion layer 30 (for example, for red color) is formed at a position corresponding to color filter layer 100a (for example, for red color).

Optionally, after step (i) in this embodiment, steps (b) through (i) can be repeated to form a patterned color conversion layer of a different type on the same substrate. For example, a second color conversion layer (for example, for green color) can be formed at a position corresponding to the color filter layer 100b (for example, for green color). Here in repeating the step (c), a newly formed protective layer 40 preferably protects the previously patterned color conversion layer 30 (FIG. 1(d), of the side face, in particular) as well as the newly formed different type of color conversion layer 30. Further as necessary, repeating the steps (b) through (i) any appropriate times, desired types of color conversion layers having each predetermined pattern can be formed on the same substrate.

In this embodiment, too, overcoat layer 70 can be optionally provided covering the lamination structure of color conversion layer 30/protective layer 40/transparent mask layer 50 to protect the side face of the color conversion layer 30, which otherwise exposes to the atmosphere (FIG. 2). Overcoat layer 70 can be formed using the same material and technique as for protective layer 40.

A third embodiment of a method of manufacturing an organic EL display according to the invention comprises steps of:

(a-1) forming a plurality of switching elements, a reflective electrode of a plurality of electrode elements each connecting to each of the plurality of switching elements in a one to one corresponding manner, and an organic EL layer on the reflective electrode;

(a-2) forming a monolithic transparent electrode on the organic EL layer;

(a-3) forming an etch stop layer over the transparent electrodes;

(b) forming a color conversion layer on the etch stop layer by means of an evaporation method;

(c) forming a protective layer covering the color conversion layer;

(d) forming a transparent mask layer on the protective layer;

(e) forming a resist layer on the transparent mask layer;

(f) patterning the resist layer in a predetermined pattern;

(g) transferring the pattern in the resist layer to the transparent mask layer using the patterned resist layer as a mask;

(h) removing the patterned resist layer; and

(i) dry etching, using the patterned transparent mask layer as a mask, to transfer the pattern from the transparent mask layer to the protective layer and the color conversion layer.

Alternatively, the steps (a-2) and (a-3) are replaced by a step (a-4) of forming, on the organic EL layers, an etch stop layer that simultaneously serves a function of a monolithic transparent electrode and is formed of an oxide containing indium or zinc.

The substrate can be formed of the same material as in the first embodiment. Nevertheless, substrate 10 in this embodiment does not transmit light. As a result, substrate 10 can be formed of an opaque material such as a semiconductor material including silicon, or a ceramic material.

In step (a-1), TFT circuits 200 are formed on the substrate as switching elements. A switching element can have a structure such as TFT or MIM known in the art. TFT circuits 200 can be formed by a known appropriate technique. Optionally, planarizing insulator film 300 for covering TFT circuits 200 and providing a flat surface on the TFT circuits can be formed except for the part that connects TFT circuits 200 and reflective electrode 210. Planarizing insulator film 300 can be formed using a material and method known in the art.

Reflective electrode 210 defines an independent light emitting area of an organic EL display of this embodiment. The reflective electrode consists of a plurality of electrode elements, each electrode element connecting to TFT circuits 200 in a one-to-one corresponding manner. Reflective electrode 210 can be formed using a highly reflective metal, Al, Ag, Mo, W, Ni, Cr or the like, an amorphous alloy (NiP, NiB, CrP, CrB or the like), or a microcrystalline alloy, NiAl or the like, by means of a dry process such as an evaporation method. Optionally, insulation layer 310 can be formed at the gap between the electrode elements of reflective electrode 210 using an insulative metal oxide (TiO₂, ZrO₂, AlOx or the like) or an insulative metal nitride (AlN, SiN or the like).

Then, organic EL layer 220 is formed on reflective electrode 210. Organic EL layer 220 comprises at least an organic light emitting layer, and as necessary, a hole injection layer, a hole transport layer, an electron transport layer and/or an electron injection layer. Specifically, a structure of an organic EL layer or an organic EL device is selected from the following layer structures:

(1) anode/organic light emitting layer/cathode

(2) anode/hole injection layer/organic light emitting layer/cathode

(3) anode/organic light emitting layer/electron injection layer/cathode

(4) anode/hole injection layer/organic light emitting layer/electron injection layer/cathode

(5) anode/hole transport layer/organic light emitting layer/electron injection layer/cathode

(6) anode/hole injection layer/hole transport layer/organic light emitting layer/electron injection layer/cathode

(7) anode/hole injection layer/hole transport layer/organic light emitting layer/electron transport layer/electron injection layer/cathode.

The anode and cathode in the above layer structures are either reflective electrode 210 or transparent electrode 230.

Known materials are used for the layers composing organic EL layer 220. The layers composing organic EL layer 220 can be formed by appropriate methods known in the art including an evaporation method. Favorably used materials for the organic light emitting layer to obtain light in the blue to blue-green color emission include fluorescent whitening agents such as benzothiazole, benzoimidazole, and benzoxazole, metal chelate oxonium compound, styrylbenzene compound, and aromatic dimethylidyne compound, for example.

Subsequently, in step (a-2), transparent electrode 230 is formed on organic EL layer 220. Transparent electrode 230 is a monolithic common electrode. Transparent electrode 230 can be formed of a conductive transparent metal oxide selected from ITO, tin oxide, indium oxide, IZO, zinc oxide, zinc-aluminum oxide, zinc-gallium oxide, and these oxides added with a dopant of fluorine, antimony or the like. Transparent electrode 230 can be formed by means of evaporation method, sputtering method, or a chemical vapor deposition (CVD) method; among them, the sputtering method is preferable.

Subsequently, in step (a-3), etch stop layer 20 is formed on transparent electrode 230. Etch stop layer 20 can be formed in the same manner as in step (a) of the first embodiment except that etch stop layer 20 is formed not on substrate 10 but on transparent electrode 230 in this embodiment.

Though the above description is made on the case in which transparent electrode 230 and etch stop layer 20 are provided separately, etch stop layer 20 made of an oxide containing indium or zinc can simultaneously function as transparent electrode 230. That is, steps (a-2) and (a-3) can be replaced by step (a-4) for forming, on the organic EL layer, an etch stop layer that simultaneously performs the function of a monolithic transparent electrode and is formed of an oxide containing indium or zinc. FIG. 3 shows an example of this alternative case, in which etch stop layer 20 simultaneously serves a function of transparent electrode 230. Oxides containing indium or zinc suited for forming etch stop layer 20/transparent electrode 230 in this alternative case include indium oxide, zinc oxide, IZO, and ITO. Etch stop layer 20/transparent electrode 230 in this alternative case can be formed in the same manner as in step (a) of the first embodiment except that the layer/electrode is formed not on substrate 10 but on organic EL layer 220 in this embodiment.

Following these steps, steps (b) through (i) are carried out in the same manner as in the first embodiment to form patterned color conversion layer 30. Patterned color conversion layer 30 is formed at a position corresponding to one of the independent light emitting areas. When color conversion layer 30 in the example of FIG. 3 converts the light emitted from organic EL layer 220 to red color light, the place provided with color conversion layer 30 becomes a red color light emitting area of the display.

Optionally, after step (i) in this embodiment, steps (b) through (i) can be repeated to form a patterned color conversion layer of a different type on the same substrate. For example, a second color conversion layer of green color conversion layer is formed and the place of the second color conversion layer is employed as a green color light emitting area of the display. Here in repeating step (c), newly formed protective layer 40 preferably protects the previously patterned color conversion layer 30 (FIG. 1(d), of the side face, in particular) as well as the newly formed different type of color conversion layer 30. Further as necessary, repeating steps (b) through (i) any appropriate number of times, desired types of color conversion layers each having a predetermined pattern can be formed on the same substrate.

In this embodiment, too, overcoat layer 70 can be optionally provided covering the lamination structure of color conversion layer 30/protective layer 40/transparent mask layer 50 to protect the side face of the color conversion layer 30, which otherwise exposes to the atmosphere (FIG. 3). Overcoat layer 70 can be formed using the same material and technique as for protective layer 40.

### EXAMPLE

Substrate 10 was a Corning 1737 glass having dimensions of 50×50×0.7 mm and used after cleaning with pure water and drying. Etch stop layer 20 was formed by depositing IZO 30 nm thick on the transparent glass substrate using an ordinary magnetron sputtering apparatus.

Then, substrate 10 having etch stop layer 20 formed thereon was transported into an evaporation apparatus and color conversion layer 30 composed of coumarin 6 and DCM-2 was produced. The color conversion layer having a film thickness of 300 nm was produced by means of co-evaporation of coumarin 6 and DCM-2 heating them in separate crucibles in the evaporation apparatus. Temperatures of the heated crucibles were controlled so as to obtain an evaporation speed of 0.3 nm/s for coumarin 6 and an evaporation speed of 0.005 nm/s for DCM-2. Color conversion layer 30 of this example contained 2 mol % of DCM-2 on the basis of total number of molecules composing the color conversion layer 30; (that is, the molar ratio of coumarin 6 : DCM-2 was 49:1).

Then, protective layer 40 was formed by depositing silicon nitride (SiNx) 300 nm thick covering color conversion layer 30 by means of a plasma CVD method using raw gases of monosilane (SiH₄), nitrogen (N₂) and ammonia (NH₃). In the process of depositing the SiNx, the lamination having color conversion layer 30 was held at a temperature not higher than 100° C. Then, transparent mask layer 50 was formed by depositing IZO 30 nm thick on protective layer 40 using an ordinary magnetron sputtering apparatus.

Then, positive type photoresist (TFR1250, a product of Tokyo Ohka Kogyou Co., Ltd.) was applied to form resist layer 60, and subsequently exposure and development processes were conducted under ordinary conditions to obtain resist layer 60 having a pattern in which stripes with a line width of 0.042 mm were arranged in parallel with a pitch of 0.126 mm. Subsequently, using a mask of the resist layer 60 having the stripe pattern, a wet etching process using an aqueous solution of oxalic acid was conducted to make a pattern on transparent mask layer 50. The resulting pattern of transparent mask layer 50 was a perfect copy of the pattern of resist layer 60. Then, resist layer 60 on the patterned transparent mask layer 50 was removed using a resist peeling liquid (No. 104 manufactured by Tokyo Ohka Kogyou Co., Ltd.) at a temperature of 40° C.

Patterning of protective layer 40 and color conversion layer 30 was carried out by reactive ion etching using a mask of the patterned transparent mask layer 50. In the patterning of protective layer 40, an etching gas of CF₄ was used. In the patterning of color conversion layer 30, an etching gas of a mixture of CF₄ and O₂ (mixing ratio of 1:1) was used. The pattern of color conversion layer 30 followed the pattern of transparent mask layer 50, that is, stripes with a line width of 0.042 mm were arranged in parallel with a pitch of 0.125 mm.

Finally, overcoat layer 70 was formed covering the pattern of color conversion layer 30/protective layer 40/transparent mask layer 50. Holding the lamination of the substrate on which the overcoat layer was formed, at a temperature not higher than 100° C., silicon nitride (SiNx) 300 nm thick was deposited by means of a plasma CVD method using raw gases of monosilane (SiH₄), nitrogen (N₂) and ammonia (NH₃) to obtain overcoat layer 70.

Thus, a method of manufacturing a patterned color conversion layer has been described according to the present invention. Many modifications and variations may be made to the techniques and structures described and illustrated herein without departing from the spirit and scope of the invention. Accordingly, it should be understood that the methods described herein are illustrative only and are not limiting upon the scope of the invention.

### DESCRIPTION OF SYMBOLS

10: substrate
20: etch stop layer
30: color conversion layer
40: protective layer
50: transparent mask layer
60: resist layer
70: overcoat layer
100 (100a, 100b, 100c): color filter layer
200: TFT circuit
210: reflective electrode
220: organic EL layer
230: transparent electrode
300: flattening insulator layer
310: insulation layer

What is claimed is:

1. A method of manufacturing a patterned color conversion layer comprising:
forming an etch stop layer on a substrate;
forming a color conversion layer on the etch stop layer by means of an evaporation method;
forming a protective layer covering the color conversion layer;
forming a transparent mask layer on the protective layer;
forming a resist layer on the transparent mask layer;
patterning the resist layer in a predetermined pattern;
transferring the pattern in the resist layer to the transparent mask layer using the patterned resist layer as a mask;
removing the patterned resist layer; and
dry etching, using the patterned transparent mask layer as a mask, to transfer the pattern from the transparent mask layer to the protective layer and the color conversion layer.

2. The method of manufacturing a patterned color conversion layer according to claim 1, wherein the etch stop layer is formed of an oxide containing an element selected from a group consisting of indium, zinc, aluminum, zirconium and titanium.

3. The method of manufacturing a patterned color conversion layer according to claim 1, wherein the transparent mask layer is formed of an oxide containing indium or zinc.

4. The method of manufacturing a patterned color conversion layer according to claim 1, wherein the color conversion layer has a thickness of at most 1 μm.

5. The method of manufacturing a patterned color conversion layer according to claim 1, wherein the dry etching method in the step (i) is a reactive ion etching method.

6. The method of manufacturing a patterned color conversion layer according to claim 1, wherein the protective layer is formed of a silicon oxide, a silicon nitride or a silicon oxide nitride, each being transparent.

7. A method of manufacturing a color conversion filter comprising:
forming one or more types of color filter layers on a substrate;
forming an etch stop layer covering the color filter layers;
forming a color conversion layer on the etch stop layer by means of an evaporation method;
forming a protective layer covering the color conversion layer;
forming a transparent mask layer on the protective layer;
forming a resist layer on the transparent mask layer;
patterning the resist layer in a predetermined pattern;
transferring the pattern in the resist layer to the transparent mask layer using the patterned resist layer as a mask;
removing the patterned resist layer; and
dry etching, using the patterned transparent mask layer as a mask, to transfer the pattern from the transparent mask layer to the protective layer and the color conversion layer.

8. A method of manufacturing an organic EL display comprising:
forming a plurality of switching elements, a reflective electrode of a plurality of electrode elements each connecting to one of the plurality of switching elements in a one to one corresponding manner, and an organic EL layer on the reflective electrode;
forming a monolithic transparent electrode on the organic EL layer;
forming an etch stop layer over the transparent electrode;
forming a color conversion layer on the etch stop layer by means of an evaporation method;
forming a protective layer covering the color conversion layer;
forming a transparent mask layer on the protective layer;
forming a resist layer on the transparent mask layer;
patterning the resist layer in a predetermined pattern;
transferring the pattern in the resist layer to the transparent mask layer using the patterned resist layer as a mask;
removing the patterned resist layer; and
dry etching, using the patterned transparent mask layer as a mask, to transfer the pattern from the transparent mask layer to the protective layer and the color conversion layer.

9. A method of manufacturing an organic EL display comprising:
forming a plurality of switching elements, a reflective electrode of a plurality of electrode elements each connecting to one of the plurality of switching elements in a one to one corresponding manner, and an organic EL layer on the reflective electrode;
forming a transparent etch stop layer of an oxide containing indium or zinc on the organic EL layer, wherein said etch layer also functions as a monolithic transparent electrode;
forming a color conversion layer on the transparent etch stop layer by means of an evaporation method;
forming a protective layer covering the color conversion layer;
forming a transparent mask layer on the protective layer;
forming a resist layer on the transparent mask layer;
patterning the resist layer in a predetermined pattern;
transferring the pattern in the resist layer to the transparent mask layer using the patterned resist layer as a mask;
removing the patterned resist layer; and
dry etching, using the patterned transparent mask layer as a mask, to transfer the pattern from the transparent mask layer to the protective layer and the color conversion layer.
